(19) United States
(12) Patent Application Publication
(10) Pub. No.: US 2003/0071632 A1
(43) Pub. Date: Apr. 17, 2003

(54) Method for determining location of a short by inferring labels from schematic connectivity

(76) Inventor: Thomas N. Indermaur, Denver, CO (US)

Correspondence Address: HEWLETT-PACKARD COMPANY, Intellectual Property Administration, P.O. Box 272400, Fort Collins, CO, 80527-2400, US

(21) Appl. No.: 09/977,699

(22) Filed: Oct. 16, 2001

(51) Int. Cl. G01R 31/08

(52) U.S. Cl. 324/512

(57) ABSTRACT

An improved method for determining location of an electrical short by inferring labels from schematic connectivity. In particular, a short locator tool, creates a copy of the artwork of the circuit where the short is located and may automatically infer additional labels from a schematic connectivity text file. By inferring additional labels for signal names on the copy of the artwork, the short locator tool is able to obtain the shortest path between two conflicting labels. The resulting error shape is thus much smaller and easier to diagnose. This method is particularly effective on power supplies and clock nets which are the most difficult shorts to diagnose.

### TECHNICAL FIELD

The technical field is locating a short in an integrated circuit, in particular, determining shortest electrical path by automatically inferring labels from schematic connectivity.

### BACKGROUND

In an integrated circuit a short occurs when two wires which are intended to be separate are accidentally connected. For example, in FIG. 1, a first wire labeled SIG1 is accidentally overlapped 10 by a second wire labeled SIG2. In this instance, a connectivity extract tool, one well known in the art, will recognize that these wires labeled SIG1, SIG2 are connected. In addition, the connectivity extract tool can recognize the overlap 10 since it is identified by two conflicting labels SIG1, SIG2 as opposed to one label.

If the extract tool recognizes two conflicting labels on one wire, the extract tool will notice the error and flag it as a short. The connectivity extractor tool will then report the shortest electrical path between the conflicting labels as shown in FIG. 2. A designer then diagnoses the problem by inspection of the error shape.

The prior art problem illustrated above would be trivial for a designer to debug. However, in real designs, some wires, particularly power supplies and clocks, may have millions of shapes and relatively few labels. In these instances, the shortest electrical path may very large and the designer may take days to diagnose the short from the information reported by the connectivity extractor tool. One way a designer may tackle this problem is to go back to the design and add more labels. With the additional labels, the shortest path between two conflicting labels may be smaller and the error shape may be easier to debug. But the process of adding additional labels by hand can also be very time consuming and error prone.

### SUMMARY

To overcome these and other problems related to determining shortest path for a short in a circuit, a method, using a short locator tool, creates a copy of the artwork of the circuit and may automatically infer additional labels from a schematic connectivity text file. By inferring additional labels for signal names on the copy of the artwork, the short locator tool is able to obtain the shortest path between two conflicting labels. The resulting error shape is then much smaller and easier to diagnose. It further eliminates the need for a designer to manually add labels. This greatly reduces the time required for diagnosing shorts and reduces the design time of integrated circuits. This method is particularly effective on power supplies and clock nets which are the most difficult shorts to diagnose.

### DESCRIPTION OF THE DRAWINGS

The detailed description will refer to the following drawings, wherein like numerals refer to like elements, and wherein:

FIG. 1 illustrates two shorted wires on a circuit;

FIG. 2 illustrates a conventional path between the shorted wires of FIG. 1;

FIG. 3a illustrates a schematic of an exemplary circuit;

FIG. 3b illustrates a textual representation of the schematic of FIG. 3a;

FIG. 3c illustrates an artwork of the schematic with shorted wires;

FIG. 4 illustrates a conventional path for the short of FIG. 3c;

FIG. 5a is a flowchart for determining location of the short of FIG. 3c;

FIG. 5b is a flowchart for determining shortest path for the short of FIG. 3c;

FIG. 6 illustrates an artwork of the schematic with inferred labels; and

FIG. 7 illustrates the shortest path for the artwork of FIG. 6.

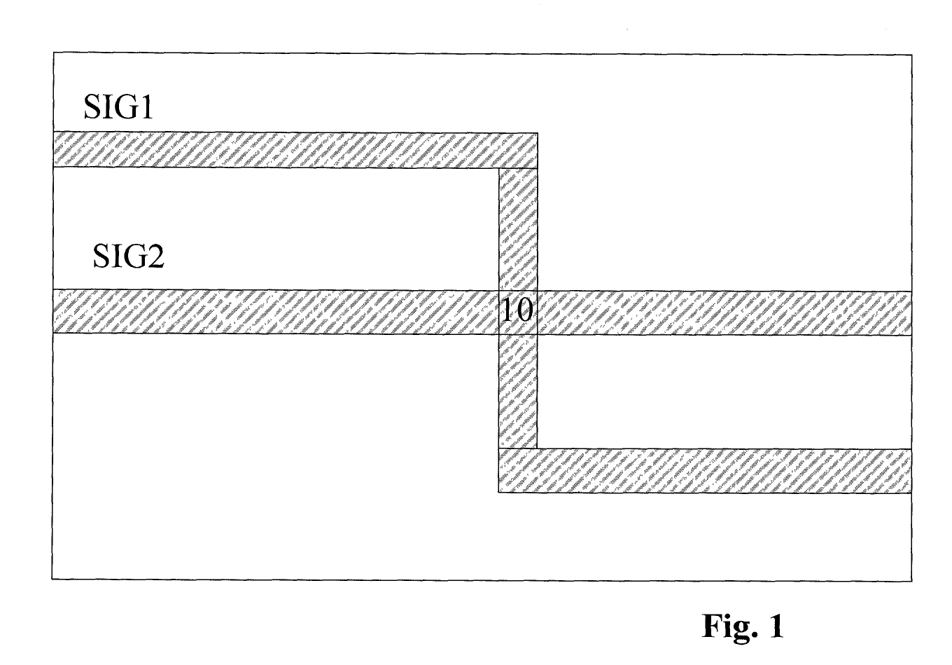

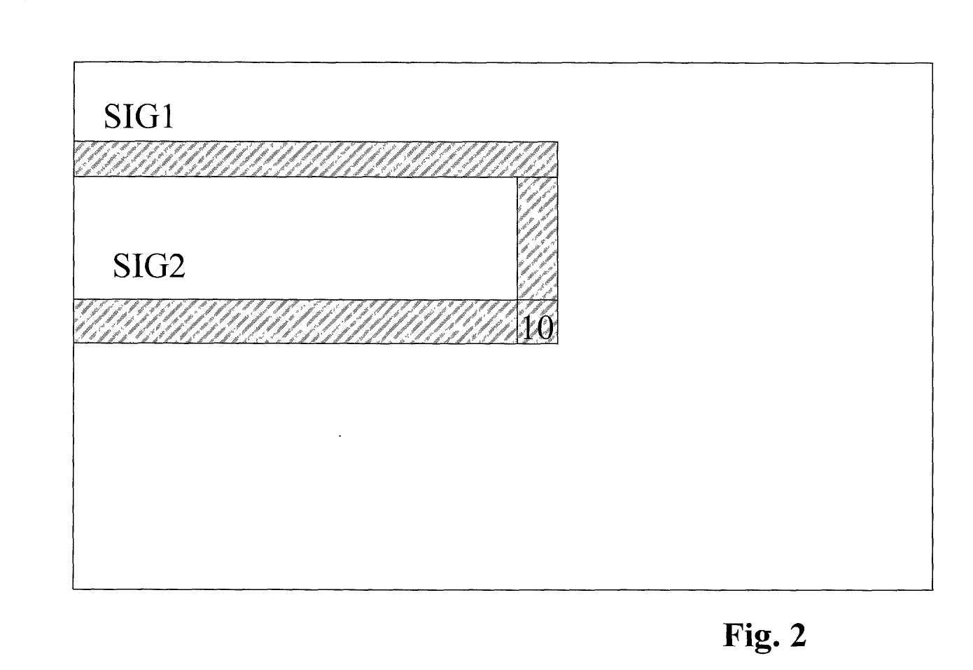

### DETAILED DESCRIPTION

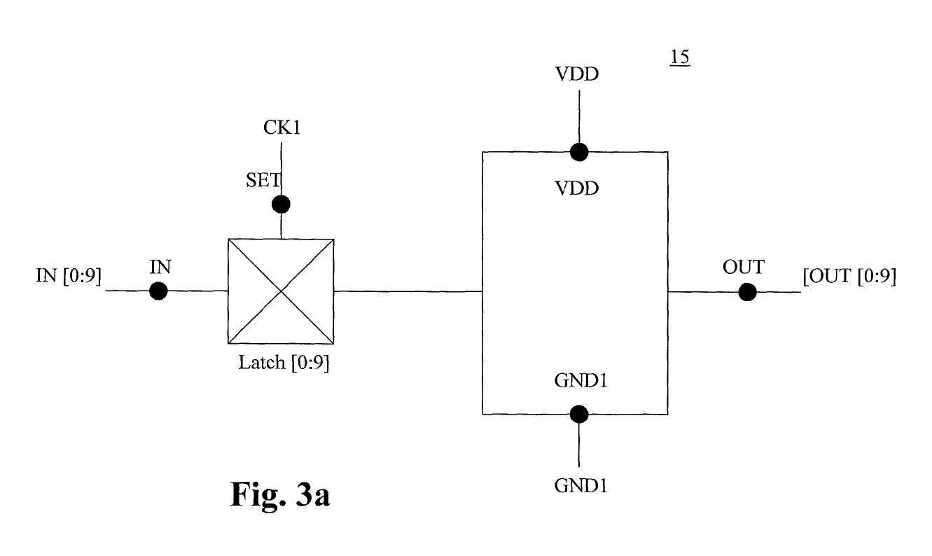

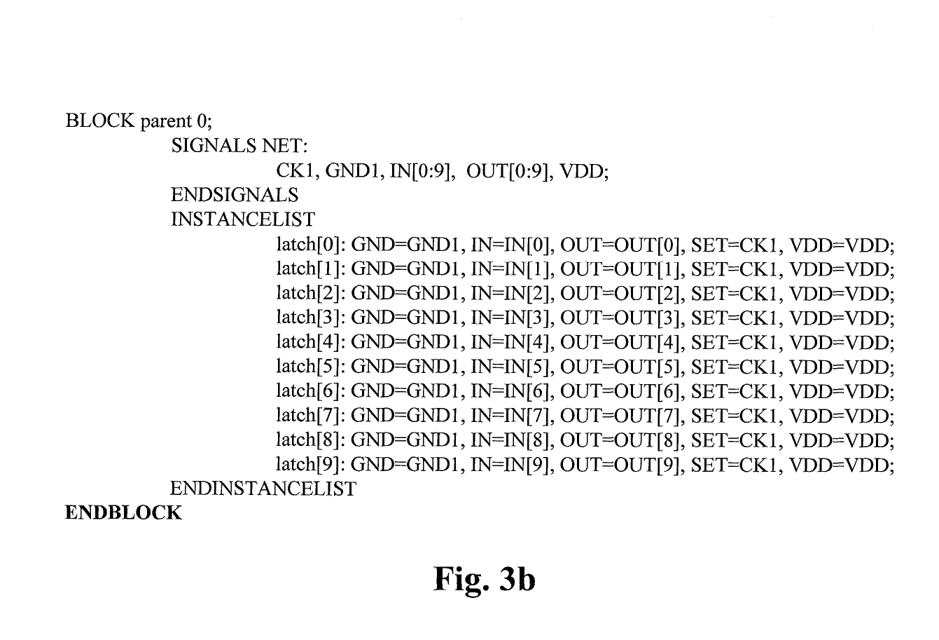

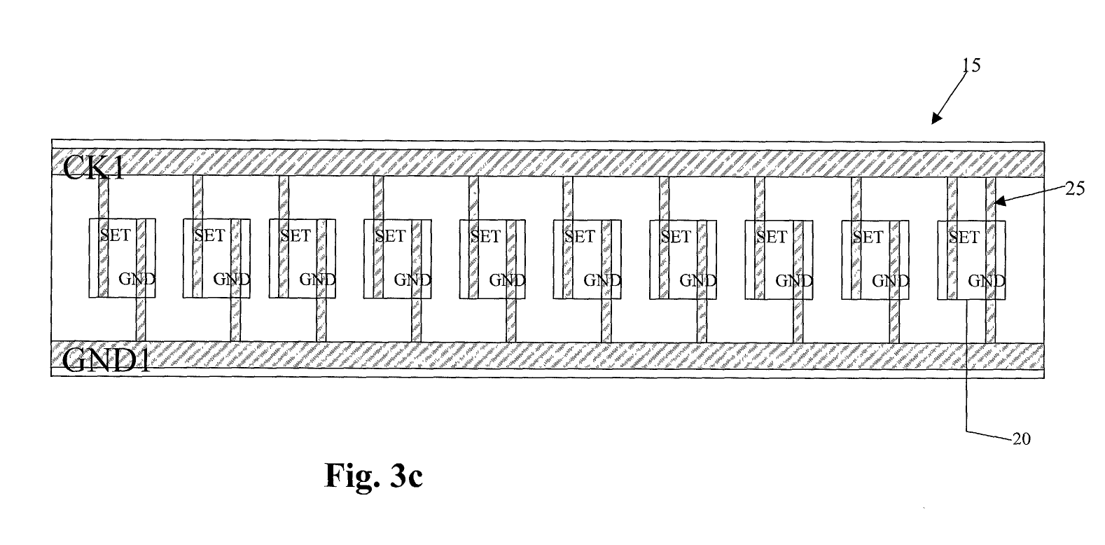

FIG. 3a is a schematic of an exemplary circuit 15. In the circuit 15, CK1 connects to SET input of ten latches, GND1 connects to GND input of the ten latches and VDD connects to VDD. The circuit 15 is exemplary and can be of various designs.

FIG. 3b is a textual representation of the schematic of FIG. 3a. The text representation lists every point of connection for the schematic. In particular, the text lists the circuit 15 containing CK1, GND1, IN [0:9], OUT [0:9] and VDD. In addition, the text lists all ten latches and what each component in each latch is connected to. For example, for latch nine, GND is connected to GND1, IN is input nine, OUT is output nine, SET is connected to CK1 and power.

FIG. 3c is an artwork of the circuit 15 of FIG. 3a with shorted wires. The artwork of the circuit 15 shows all ten latches and the wire connection for SET and GND. As stated above, the CK1 wire connects the SET ports together and the GND1 wire connects the GND ports together. However, in latch nine 20, the GND wire and the SET wire are accidentally connected 25 because the GND wire connects to CK1 and thereby creates a short.

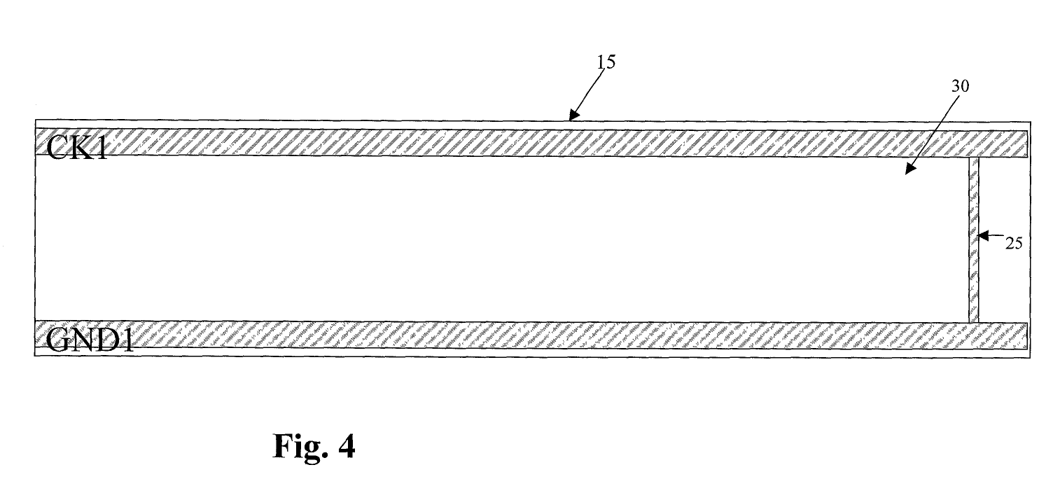

If a designer were to use a conventional connectivity extractor tool on FIG. 3c to determine the path between conflicting labels for the short 25, the extractor tool would produce an error shape 30 shown in FIG. 4. Since the labels are all the way on the left side of the artwork and the short 25 is all the way on the right side of the artwork, the error shape 30 encloses the entire circuit 15. A designer would have to go through the entire circuit 15 to determine where the short 25 occurs. Depending on the size of the circuit 15, this could take the designer days before determining where this one short 25 occurs.

For the present invention, once a short has been determined by the connectivity extract tool, the tool may invoke a short locator tool to determine the shortest error shape for the short 25. The short locator tool can be automatically activated by the connectivity extract tool or the connectivity extract tool can notify a designer who may then activate the short locator tool.

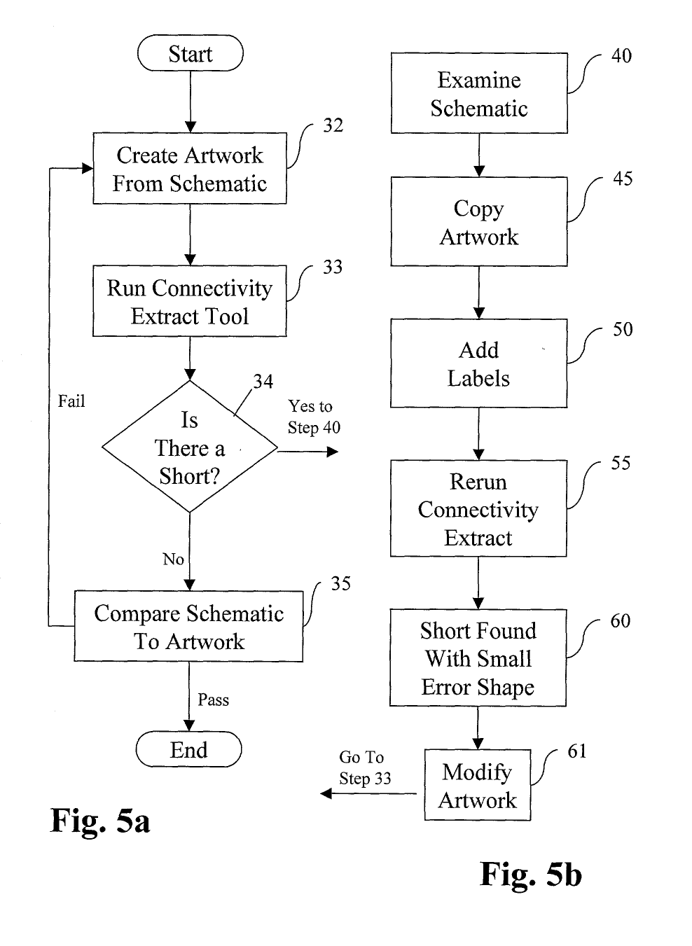

FIG. 5a illustrates a method for determining location of the short 25. Once the designer obtains a schematic of the circuit 15, as shown in FIG. 3a, the designer creates an artwork (FIG. 3c) of the circuit 15 from the schematic (step 32). Once the artwork is completed, the designer runs the connectivity extract tool on the artwork to determine valid connection (step 33). While the connectivity extract tool is running, the tool determines if a short exists (step 34). If a short 25 does exist, the short locator tool will be activated. This will be discussed below with respect to FIG. 5b. If a short does not exist, this means the extract tool was able to obtain valid electrical connectivity for the artwork and will now compare the schematic of the circuit 15 to the artwork (step 35). If all the connections are valid, the connectivity extractor tool will pass, otherwise it will fail and return to the artwork (step 32). At this point, if the connectivity extract tool fails, it does not mean a short exists in the artwork, but rather, a label or signal name has been misspelled by the designer. The designer will then go back to the artwork to check all labels or signal names.

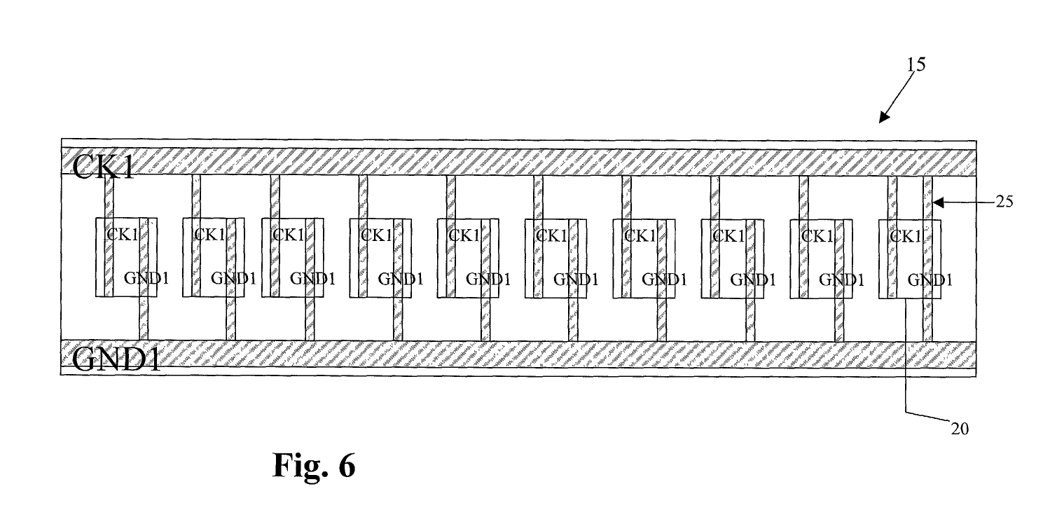

FIG. 5b illustrates one method the short locator tool uses for determining the shortest electrical path for the short 25. Initially, the short locator tool examines the schematic of the circuit 15 (step 40). The locator tool evaluates the connectivity text file of the schematic as shown in FIG. 3b. From the text file, the locator tool knows what the SET and GND ports should be connected to. In this instance, all the SET ports should be connected to CK1 and all the GND ports should be connected to GND1. The locator tool then makes a copy of the artwork shown in FIG. 3c (step 45). The short locator tool does not use the original artwork because the locator tool may be adding a large number of labels which may make the original artwork more difficult for a designer to understand and maintain. Now that a copy of the artwork has been made and the locator tool has examined the text file, the tool knows that all SET ports are suppose to be connected to CK1 and all GND ports are suppose to be connected to GND1. The locator tool will now infer and rename CK1 label for all SET labels and GND1 label for all GND label (step 50). Once all the labels have been inferred, as shown in FIG. 6, the short locator tool invokes the connectivity extract tool. The connectivity extract tool is run again on the copy of the artwork with the inferred labels (step 55). Once the connectivity extract tool is run, the extract tool locates the shortest electrical path between two conflicting labels (step 60).

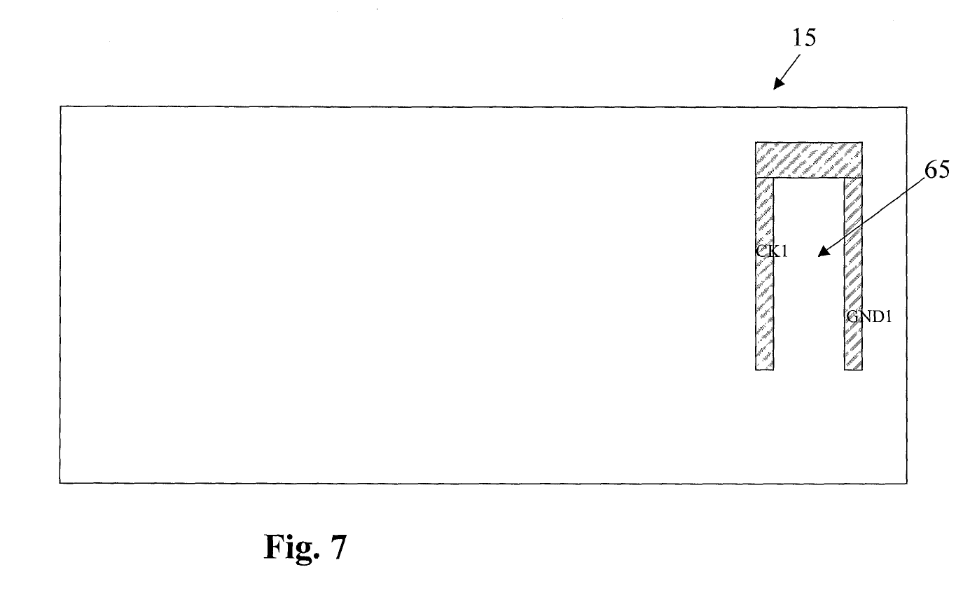

The extract tool will look at each latch and see that all CK1 ports are connected to CK1 and all GND1 ports are connected to GND1. However, the tool will recognize that for latch nine 20, GND1 is connected to both CK1 and GND1. The tool will then generate a shorter error shape 65, as shown in FIG. 7. By using the inferred labels, the error shape 65 for the short is limited to that of latch nine. This error shape 65 points the designer much closer to the actual short as opposed to the error shape 30 of FIG. 4 where it contained the entire circuit 15. Once the shorter error shape 65 is determined, the designer can modify the artwork (step 61) and run the connectivity extractor tool on the modified artwork.

While the above is described with reference to exemplary embodiments, many modifications will be readily apparent to those skilled in the art, and the present disclosure is intended to cover variations thereof.

In the claims:

1. A method for determining location of a short in a circuit, comprising the steps of:
(a) running a connectivity extract tool on an artwork of the circuit;
(b) determining if a short exists in the circuit, wherein if a short exists the method comprises:
running a short locator tool; and
(c) comparing the artwork of the circuit to a schematic of the circuit.

2. The method of claim 1 wherein the step of running a short locator tool further comprises the steps of:
examining a schematic of the circuit;
creating a copy of the artwork of the circuit; and
inferring labels to the copy of the artwork.

3. The method of claim 2 where in the step of examining further comprises the step of evaluating a connectivity text file of the schematic.

4. The method of claim 3 wherein the step of evaluating further comprises obtaining electrical connection information for each component.

5. The method of claim 2 wherein the step of inferring further comprises the step of renaming signal names.

6. The method of claim 2 further comprising the step of running the connectivity extract tool on the copy of the artwork.

7. The method of claim 6 further comprising obtaining shortest path between conflicting labels in the circuit.

8. The method of claim 7 further comprising modifying artwork of the circuit.

9. The method of claim 8 further comprising running the connectivity extract tool on the modified artwork.

10. A method for determining shortest path for a short in a circuit comprising the steps of:
examining a schematic of the circuit;
creating a copy of the artwork of the circuit; and
inferring labels to the copy of the artwork.

11. The method of claim 10 where in the step of examining further comprises the step of evaluating a connectivity text file of the schematic.

12. The method of claim 11 wherein the step of evaluating further comprises obtaining electrical connection information for each component in the circuit.

13. The method of claim 10 wherein the step of inferring further comprises the step of renaming common connection signal names.

14. The method of claim 10 further comprising the step of running a connectivity extract tool on the copy of the artwork.

15. The method of claim 14 further comprising obtaining shortest path between conflicting labels in the circuit.

16. The method of claim 15 further comprising modifying artwork of the circuit.

17. The method of claim 16 further comprising running the connectivity extract tool on the modified artwork.
